(19) United States
(12) Patent Application Publication
(10) Pub. No.: US 2015/0259788 A1
(43) Pub. Date: Sep. 17, 2015

(54) SPUTTERING APPARATUS AND MANUFACTURING METHOD OF MAGNETORESISTIVE ELEMENT

(71) Applicants: Makoto NAGAMINE, Seoul (KR); Youngmin EEH, Seoul (KR); Koji UEDA, Seoul (KR); Daisuke WATANABE, Seoul (KR); Kazuya SAWADA, Seoul (KR); Toshihiko NAGASE, Seoul (KR); Tokuhisa OHIWA, Seoul (KR)

(72) Inventors: Makoto NAGAMINE, Seoul (KR); Youngmin EEH, Seoul (KR); Koji UEDA, Seoul (KR); Daisuke WATANABE, Seoul (KR); Kazuya SAWADA, Seoul (KR); Toshihiko NAGASE, Seoul (KR); Tokuhisa OHIWA, Seoul (KR)

(21) Appl. No.: 14/479,216

(22) Filed: Sep. 5, 2014

Related U.S. Application Data
(60) Provisional application No. 61/952,818, filed on Mar. 13, 2014.

(51) Int. Cl. C23C 14/35; H01J 37/34

(52) U.S. Cl. CPC C23C 14/352; H01J 37/3417

(57) ABSTRACT

According to one embodiment, a sputtering apparatus includes a first chamber configured to form a magnetic film on a substrate and a second chamber configured to form a non-magnetic film on the substrate, which are disposed to be adjacent to each other so that the substrate is conveyable between the chambers. A magnetic target is provided in the first chamber, and a non-magnetic target and a low dielectric-constant target having a dielectric constant lower than that of the non-magnetic target are provided in the second chamber. Here, before the non-magnetic target is formed on the substrate by sputtering, the low dielectric-constant target is subjected to sputtering in the second chamber, thereby depositing a low dielectric-constant material on the inner surface of the second chamber.

### CROSS-REFERENCE TO RELATED APPLICATIONS

This application claims the benefit of U.S. Provisional Application No. 61/952,818, filed Mar. 13, 2014, the entire contents of which are incorporated herein by reference.

### FIELD

Embodiments described herein relate generally to a sputtering apparatus and a method for manufacturing a magnetoresistive element using the apparatus.

### BACKGROUND

Recently, large-capacity magnetoresistive random access memories (MRAM) which employ a magnetic tunnel junction (MTJ) are a promising focus of development. The MTJ element used for an MRAM comprises two ferromagnetic layers (CoFeB) between which a tunnel barrier layer (MgO) is sandwiched, one layer being assigned as a magnetization fixed layer (reference layer) in which the direction of magnetization is not to change, and the other as a magnetization free layer (memory layer) in which the direction of magnetization can be easily reversed.

When the directions of magnetization of the reference layer and memory layer are parallel to each other, the resistance of the tunnel barrier layer (barrier resistance) is lower and the tunnel current is greater than when the directions of magnetization are antiparallel. Here, the MR ratio is defined as: MR ratio=(Resistance in antiparallel state−Resistance in parallel state)/Resistance in parallel state. In a conventional method of manufacturing an MTJ element, generally, a sputtering apparatus is used to form an MgO tunnel barrier layer. However, with this method, high-quality MgO cannot be formed, which makes it difficult to achieve a high MR ratio.

### BRIEF DESCRIPTION OF THE DRAWING

FIG. 1 is a schematic structural diagram showing an apparatus for manufacturing a magnetoresistive element, according to a first embodiment;

FIG. 2 is a cross-sectional view showing a structure of a second chamber of the manufacturing apparatus shown in FIG. 1;

FIGS. 3A and 3B are schematic diagrams illustrating a manufacturing process of an MgO layer;

FIG. 4 is a circuit structural diagram showing an MRAM which employs a magnetoresistive element;

FIG. 5 is a cross-sectional view showing a structure of a magnetoresistive element; and

FIG. 6 is a cross sectional view showing a structure of a main portion of an apparatus for manufacturing a magnetoresistive element, according to a second embodiment.

### DETAILED DESCRIPTION

In general, according to one embodiment, there is provided a sputtering apparatus comprising: a first chamber configured to form a magnetic film on a substrate; a magnetic target disposed in the first chamber; a second chamber configured to form a non-magnetic film on the substrate, the second chamber being provided adjacent to the first chamber and configured to convey the substrate between the first chamber and the second chamber; a non-magnetic target disposed in the second chamber; and a low dielectric-constant target disposed in the second chamber and configured to deposit a low dielectric-constant material having a dielectric constant lower than that of the non-magnetic target, on the inner surface of the chamber by sputtering.

Embodiments will now be described in detail with reference to drawings.

### First Embodiment

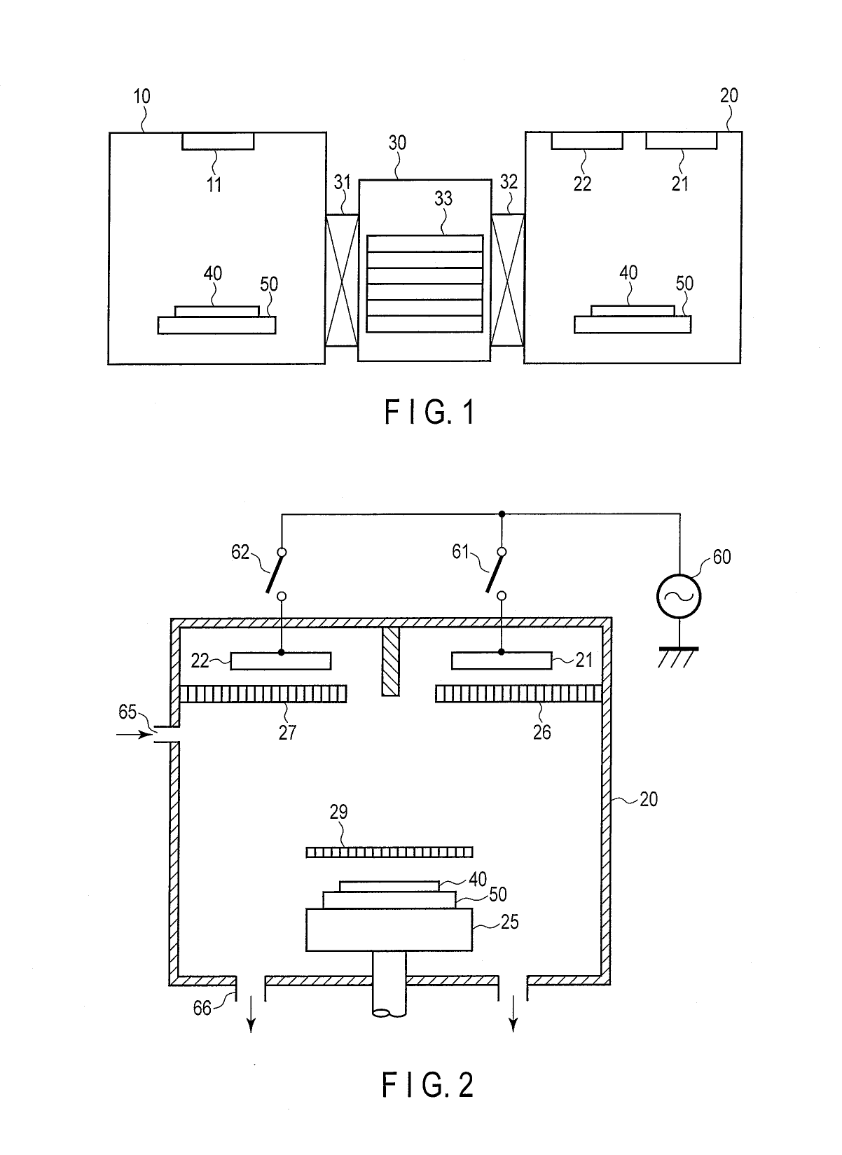

FIG. 1 is a schematic structural diagram showing an apparatus for manufacturing a magnetoresistive element, according to the first embodiment.

A first chamber 10 and a second chamber 20 are connected to each other via a transfer chamber 30. A gate valve 31 is provided between the transfer chamber 30 and the first chamber 10, whereas a gate valve 32 is provided between the transfer chamber 30 and the second chamber 20.

The first chamber 10 is configured to form a ferromagnetic film of a magnetoresistive element and to accommodate therein a stage 50 on which a substrate 40 is placed. On an upper section of the chamber 10, a CoFeB target (magnetic material target) 11, which is a ferromagnetic material is provided as a sputtering source. When the target 11 is subjected to RF sputtering in an Ar gas atmosphere, a CoFeB film can be formed on the substrate 40.

The second chamber 20 is configured to form a non-magnetic tunnel barrier film of a magnetoresistive element and to accommodate therein a stage 50 on which a substrate 40 is placed. On an upper section of the second chamber 20, an MgO target (nonmagnetic material target) 21, which serves as a sputtering source, and an insulating film having a dielectric constant lower than that of MgO, for example, an aluminum oxide (Al₂O₃) target (low dielectric-constant target) 22 are provided. When the MgO target 21 is subjected to sputtering in an Ar gas atmosphere, an MgO film can be formed on the substrate 40. Further, when the Al₂O₃ target 22 is subjected to sputtering in an Ar gas atmosphere, an Al₂O₃ film can be deposited on the inner surface of the second chamber 20.

A magazine 33 configured to accommodate a plurality of substrates 40 or substrate stages 50 is contained in the transfer chamber 30. Here, the substrates 40 or substrate stages 50 on which the substrates are placed can be transferred to each other between the chambers 10 and 20 while maintaining the airtight states of the chambers 10 and 20.

The structure of the second chamber 20 will be described in further detail with reference to FIG. 2.

On a lower portion of the second chamber 20, a rotating stage 25 which can be driven by a motor (not shown) or the like is provided. On the rotating stage 25, a substrate stage 50, on which a substrate 40 is placed, can be mounted. On the upper section of the second chamber 20, the MgO target 21 and Al₂O₃ target 22 are disposed.

In front of the MgO target 21 (shown as being under the target in the figure), a shutter 26 is provided, and similarly, in front of the Al₂O₃ target 22 (shown as being under the target), a shutter 27 is provided. The shutters 26 and 26 are configured to open after discharge is stabilized in the sputtering of the targets. Further, above the rotating stage 25, a sub-shutter 29 is provided, which is configured to temporarily cover the surfaces of the substrate 40 and substrate stage 50.

The target 21 is connected to an RF power source 60 via a switch 61, and the target 22 is connected to the RF power source 60 via a switch 62. As the switch 61 and/or switch 62 are/is selected, RF power can be applied selectively to the target 21 and/or target 22.

The second chamber 20 is provided with a gas inlet 65 configured to introduce an inert gas of Ar or the like. Further, the second chamber 20 is provided with an exhaust outlet 66 configured to evacuate the inside thereof.

Next, a method of manufacturing a magnetoresistive element, which employs this apparatus, will now be described.

First, one of a plurality of substrates 40 accommodated in the magazine 33 of the transfer chamber is conveyed into the first chamber 10. In the first chamber 10, the CoFeB target 11 is subjected to RF sputtering in an Ar gas atmosphere, to form a CoFeB film on the substrate 40. Note here that the conveyance of the substrate 40 may be carried out by moving only the substrate 40 itself, or the substrate stage 50 on which the substrate 40 is placed.

Next, the substrate 40 on which the CoFeB film is formed is conveyed into the second chamber 20 via the transfer chamber 30. Then, the substrate stage 50 is set on the rotating stage 25. Here, since the first chamber 10 is now empty, a CoFeB film may be formed on another substrate 40 in the first chamber 10. More specifically, the next substrate is conveyed from the transfer chamber 30 into the first chamber 10, and CoFeB film can be formed on the next substrate 40 by a similar process to that described above.

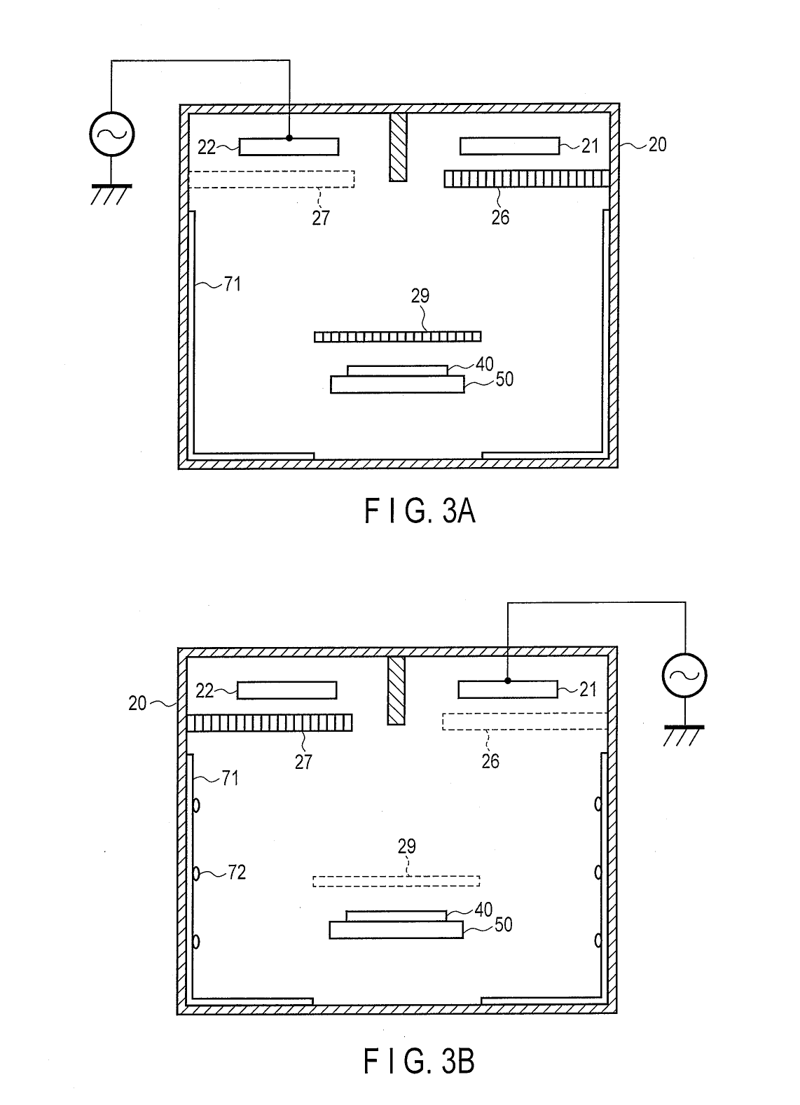

In the second chamber 20, while the shutter 27 is opened and the shutter 26 and the sub-shutter 29 are closed as shown in FIG. 3A, RF power is applied to the Al₂O₃ target 22, and thus Al₂O₃ is subjected to RF sputtering in an Ar gas atmosphere. In this manner, an Al₂O₃ film 71 is deposited on the inner surface of the second chamber 20 without being deposited on the substrate 40 or substrate stage 50. Note that the apparatus is configured such that after the discharge is stabilized, the shutter 27 of the target 22 is opened.

Next, while the shutter 27 is closed and the shutter 26 and the sub-shutter 29 are opened as shown in FIG. 3B, RF power is applied to the MgO target 21, and thus MgO is subjected to RE sputtering in an Ar gas atmosphere. In this manner, an MgO film is formed on the substrate 40. At the same time, an MgO film 72 is formed on the inner surface of the second chamber 20, as well. Note that after the discharge is stabilized, the shutter 26 of the target 21 is opened. Further, in order to deposit the MgO film evenly, the rotating stage 25 is rotated during the sputtering.

Subsequently, the substrate stage 50 on which the substrate 40 is placed is conveyed into the transfer chamber 30, and this substrate 40 is conveyed into the first chamber 10. Here, the second chamber 20 is now empty, and therefore an MgO film may be formed on another substrate in the chamber 20. More specifically, the next substrate 40 is conveyed from the transfer chamber 30 into the second chamber, and thus the MgO film can be formed on the next substrate 40 by a similar process to that described above.

Subsequently, the substrate 40 conveyed into the first chamber is subjected to sputtering of the CoFeB target 11 once again, and thus a CoFeB film is formed on the substrate 40. As described above, a CoFeB film, an MgO film and a CoFeB film are deposited in order on the substrate 40, and thus a magnetoresistive element in which an MgO tunnel barrier layer is interposed between CoFeB ferromagnetic layers can be prepared.

Here, with regard to the formation of an MgO film in the second chamber 20, if sputtering of the MgO target 21 is carried out without sputtering of a target having a low dielectric constant as in the conventional techniques, MgO is deposited partially on the inner surface of the chamber 20. If MgO is deposited on the inner surface of the second chamber 20, the deposited MgO will serve as a capacitor. Further, partial depositions of MgO form a discontinuous capacitor, which makes plasma instable.

Experiments conducted by the authors of the present embodiment showed that MgO attached to the inner surface of the second chamber 20 serves to increase the target voltage Vdc while forming MgO film, and further Vdc greatly vary. These results may cause degradation of the quality or reproducibility of the MgO film formed on the substrate 40.

By contrast, according to the present embodiment, before the formation of the MgO film, a target having a dielectric constant lower than that of MgO is subjected to sputtering to deposit a low dielectric-constant material on the inner surface of the second chamber 20. With this process, even if MgO is deposited on the inner surface of the chamber by the sputtering of MgO, the total capacitance reduced. When the capacitance is reduced, Vdc is reduced and the variation of Vdc is suppressed. Consequently, the plasma is stabilized. Therefore, the quality and reproducibility of the MgO film formed on the substrate 40 can be enhanced.

Note that the experiments conducted by the authors of the present embodiment have confirmed that the reduction of Vdc and suppression of the variation thereof stabilizes plasma. This is considered to be for the following reasons:

(1) Al₂O₃, which has a dielectric constant lower than that of MgO, is deposited more uniformly than MgO on the inner surface of the chamber.

(2) MgO is deposited more uniformly on Al₂O₃ than it is when deposited directly on the inner surface of the chamber.

(3) The capacitance is lower when MgO is deposited by laminating it with Al₂O₃ on the inner surface of the chamber than it is when MgO is deposited.

The above-described phenomenon is not necessarily limited to the case where MgO is used as a non-magnetic material, but also occurs when another non-magnetic material is used. In consideration of the fact that the effect can be obtained by depositing Al₂O₃, which has a dielectric constant lower than that of MgO, in advance on the inner surface of the chamber, the above-mentioned other non-magnetic material of the low dielectric-constant target may be any type as long as it has a dielectric constant lower than that of the non-magnetic material to be formed on the substrate.

Another significance of the embodiment is the deposition of not a metal such as Ta, but a low-dielectric constant material such as Al₂O₃ on the inner surface of the chamber by sputtering. More specifically, if MgO grows in an island manner, a drawback occurs, in which the capacitance varies greatly. As described above, the capacitance can be stabilized by uniformly depositing the insulating layer (Al₂O₃) as in the present embodiment. Even if a metal such as Ta is deposited on the inner surface of the chamber in advance, the effect of stabilization of the capacitance cannot be obtained.

As described above, according to this embodiment, Al₂O₃ is deposited on the inner surface of the chamber 20 by sputtering of the Al₂O₃ target 22 as a pre-stage for the formation of the MgO film. With this pre-stage, the variation of the target voltage Vdc for the formation of the MgO film by sputtering can be reduced, and the voltage Vdc can be lowered. Therefore, the quality of the MgO film formed on the substrate 40 can be improved, and the reproducibility thereof can be enhanced. Thus, the MR ratio of the MTJ element can be increased.

Further, this embodiment comprises the transfer chamber 30 and magazine 33 between the first and second chambers 10 and 20. With this structure, it is possible to process separate substrates 40 in the first and second chambers 10 and 20 at the same time. That is, while forming an MgO film in the second chamber 20, a CoFeB film may be formed on a separate substrate in the first chamber 10. With this structure, the production throughput can be improved.

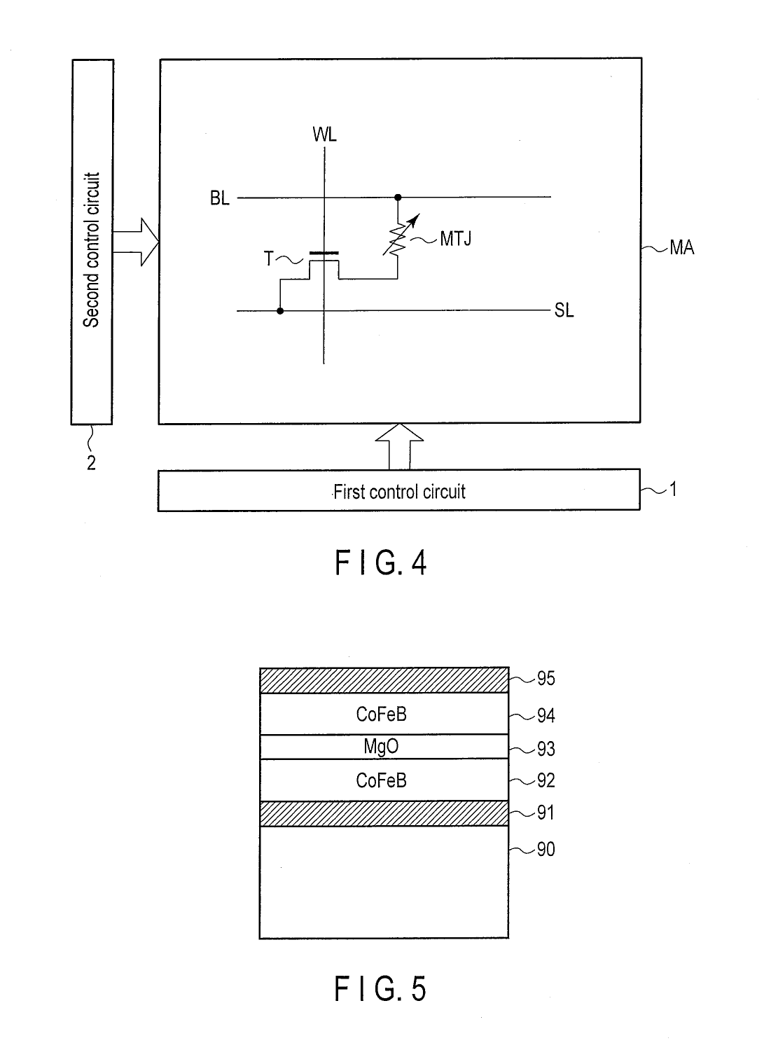

FIG. 4 is a circuit structural diagram showing a memory cell array of an MRAM which employs a magnetoresistive element of this embodiment.

A memory cell in the memory cell array MA comprises a serial connector between a magnetoresistive element (MTJ element) and a switch element (for example, a field-effect transistor (FET)) T. One end of the serial connector (that is, one end of the magnetoresistive element 30) is electrically connected to a bit line BL, while the other end of the serial connector (that is, one end of the switch element T) is electrically connected to a source line SL.

A control terminal of the switch element T, for example, a gate electrode of the FET, is electrically connected to a word line WL. The potential of the word line WL is controlled by a first control circuit 1. The potentials of the bit line BL and source line SL are controlled by a second control circuit 2.

A basic structure of the MTJ element is, for example, as shown in FIG. 5. That is, a lower electrode 91 is formed on a semiconductor substrate 90. On the lower electrode 91, a CoFeB film 92 serving as a ferromagnetic magnetization fixed layer, an MgO film 93 serving as a non-magnetic tunnel barrier layer, and a CoFeB film 94 serving as a ferromagnetic magnetization free layer are stacked. In other words, the MTJ element has a structure in which the tunnel barrier layer is interposed between the ferromagnetic layers. Further, an upper electrode 95 is formed on the CoFeB film 94.

The apparatus of this embodiment is configured to form a laminated structure of the MTJ element, and in particular, with this apparatus, which deposits a low dielectric-constant material in the chamber 20 in advance when forming the MgO film 93, the quality and reproducibility of the MgO film 93 can be improved.

### Second Embodiment

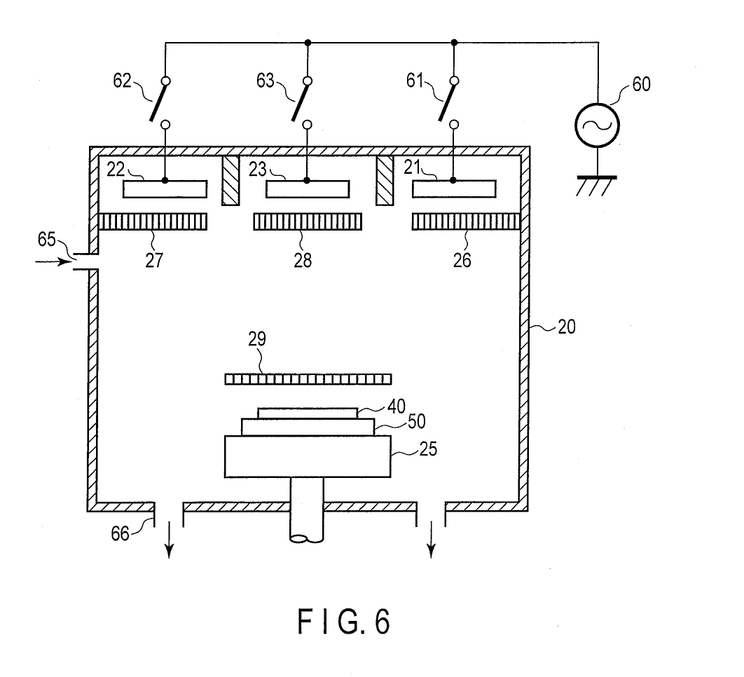

FIG. 6 is shows an apparatus for manufacturing a magnetoresistive element, according to the second embodiment, in particular, the structure of the second chamber. The same structural members as those shown in FIG. 2 will be designated by the same reference numbers, and detailed explanations therefor will be omitted.

The basic structure is similar to that of the first embodiment, and this embodiment is different from the first embodiment described before in the structure of the second chamber 20.

A Ta target 23 having a gettering effect on oxygen, water or the like is provided together with targets 21 and 22 in the second chamber 20. A shutter 28 is provided on a substrate side of the target 23. The target 23 is connected to an RF power source 60 via a switch 63.

In order to form an MgO film with this apparatus, the Al₂O₃ target 22 is subjected to sputtering while the shutter 27 is open and the shutters 26 and 29 are closed, and thus a low dielectric-constant material is deposited on the inner surface of the chamber 20.

Subsequently, the shutter 27 is closed and the shutter 28 is opened, the Ta target 23 is subjected to sputtering, and thus a low dielectric-constant material is deposited on the inner surface of the chamber 20. With the formation of the Ta film, the gettering effect on oxygen, water, etc., in the chamber 20 is improved.

After that, the MgO target 21 is subjected to sputtering while the shutters 27 and 28 are closed and the shutter 26 and the sub-shutter 29 are opened, and thus an MgO film is formed on the substrate 40.

Naturally, with the deposition of an MgO film as described above, an advantageous effect similar to that of the first embodiment can be obtained. In addition, oxidizing gases of oxygen, water, etc., released from the chamber and other structural members during the formation of the MgO film are captured and removed by the Ta film deposited on the inner surface of the chamber. Therefore, the MgO film can be deposited on the substrate 40 in such a state that the oxidizing gases in the chamber 20 are reduced in quantity, and thus the quality of the MgO film can be further improved. Consequently, an MTJ element having a high MR ratio can be achieved.

### Modified Examples

Note that the embodiments are not limited to those discussed above.

More specifically, the non-magnetic target is not necessarily limited to MgO, but it may be of any material as long as it can function as a tunnel barrier layer of an MTJ element. For example, AlN, AlON, Al₂O₃ or the like can be employed. Further, the low dielectric-constant target is not limited to Al₂O₃, but may be of any material as long as it has a dielectric constant lower than that of the non-magnetic target. For example, an Si oxide, Si nitride, Al oxide, Al nitride or Zn oxide can be employed.

Furthermore, the magnetic target is not necessarily limited to CoFeB, but it may be of any ferromagnetic material as long as it can form an MTJ element. The target for gettering oxygen, water, etc., is not limited to Ta, but CuN, CoFe, CoFeB, Ru, Ti, Mg, Cr, Zr or the like can be employed.

In the meantime, the above-provided embodiments are discussed in connection with an example of RF sputtering using an RF power source, but the embodiments are also applicable to DC sputtering. For example, it is also possible to employ an Al target and carry out sputtering in an O gas atmosphere. Further, the embodiments can be applied not only to such a system that a low dielectric-constant material is deposited on the inner surface of the chamber each time a substrate is processed, but also to such a system that a low dielectric-constant material is deposited on the inner surface of the chamber each time a certain number of substrates are processed.

Further, in the above-provided embodiments, the magnetic film and non-magnetic film are formed in separate chambers, respectively, but it is also possible to form these films sequentially in a single chamber. In this case, any system may be used as long as it is such that one chamber may comprise a magnetic target, a non-magnetic target and a low dielectric-constant target and sputtering can be performed by selecting a target from these.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A sputtering apparatus comprising:
a chamber configured to accommodate a substrate;
a non-magnetic target disposed in the chamber and configured to form a non-magnetic film on the substrate by sputtering; and
a low dielectric-constant target disposed in the chamber and configured to deposit a low dielectric-constant material having a dielectric constant lower than that of the non-magnetic film, on an inner surface of the chamber by sputtering.

2. The apparatus of claim 1, further comprising a magnetic target disposed in the chamber and configured to form a magnetic film on the substrate by sputtering.

3. The apparatus of claim 1, further comprising:
another chamber provided adjacent to the chamber; and
a magnetic target disposed in the another chamber and configured to form a magnetic film on the substrate by sputtering.

4. The apparatus of claim 1, further comprising a shutter disposed between the substrate and the low dielectric-constant target in the chamber.

5. The apparatus of claim 1, wherein the non-magnetic target contains MgO, the low-dielectric constant target contains one of an Si oxide, Si nitride, Al oxide, Al nitride and Zn oxide.

6. The apparatus of claim 1, wherein each sputtering is an RF sputter.

7. A sputtering apparatus comprising:
a first chamber configured to form a magnetic film on a substrate;
a magnetic target disposed in the first chamber;
a second chamber configured to form a non-magnetic film on the substrate, the second chamber being provided adjacent to the first chamber and configured to convey the substrate between the first chamber and the second chamber;
a non-magnetic target disposed in the second chamber; and
a low dielectric-constant target disposed in the second chamber and configured to deposit a low dielectric-constant material having a dielectric constant lower than that of the non-magnetic target, on an inner surface of the chamber by sputtering.

8. The apparatus of claim 7, further comprising a transfer chamber provided between the first chamber and the second chamber and configured to convey the substrate between the first chamber and the second chamber without exposing the substrate to atmosphere.

9. The apparatus of claim 8, wherein the substrate is placed on a substrate stage, and the substrate stage is conveyable between the first chamber and the second chamber.

10. The apparatus of claim 7, further comprising a shutter disposed between the substrate and the low dielectric-constant target in the second chamber.

11. The apparatus of claim 7, wherein the magnetic target contains CoFeB.

12. The apparatus of claim 7, wherein the non-magnetic target contains MgO.

13. The apparatus of claim 7, wherein the low dielectric-constant target contains one of an Si oxide, Si nitride, Al oxide, Al nitride and Zn oxide.

14. The apparatus of claim 7, wherein the sputtering is an RF sputter.

15. A method of manufacturing a magnetoresistive element, comprising:
forming a first magnetic film on a substrate;
sputtering a low-dielectric constant target having a dielectric constant lower than that of a non-magnetic film in a chamber, thereby depositing a low dielectric-constant material on an inner surface of the chamber;
sputtering a non-magnetic target in the chamber after the deposition of the low dielectric-constant material, thereby forming the non-magnetic film on the first magnetic film; and
forming a second magnetic film on the non-magnetic film.

16. The method of claim 15, wherein
the forming the first magnetic film comprises sputtering a magnetic target provided in the chamber, thereby depositing the first magnetic film on the substrate; and
the forming the second magnetic film comprises sputtering the magnetic target in the chamber, thereby depositing the second magnetic film on the non-magnetic film.

17. The method of claim 15, wherein
the forming the first magnetic film comprises sputtering a magnetic target in another chamber separate from the chamber, thereby depositing the first magnetic film on the substrate; and
the forming the second magnetic film comprises sputtering the magnetic target in the another chamber, thereby depositing the second magnetic film on the non-magnetic film.

18. The method of claim 17, wherein the substrate is placed on a substrate stage, and the substrate stage conveyed between the chamber and the another chamber.

19. The method of claim 15, wherein the non-magnetic target contains MgO, and the low dielectric-constant target contains one of an Si oxide, Si nitride, Al oxide, Al nitride and Zn oxide.
